(19) United States
(12) Patent Application Publication
(10) Pub. No.: US 2015/0348986 A1
(43) Pub. Date: Dec. 3, 2015

(54) NON-VOLATILE MEMORY AND METHOD OF FORMING THE SAME

(71) Applicant: MACRONIX International Co., Ltd., Hsinchu (TW)

(72) Inventor: Yu-Chung Chen, Hsinchu (TW)

(21) Appl. No.: 14/656,294

(22) Filed: Mar. 12, 2015

(30) Foreign Application Priority Data
Nov. 23, 2012 (CN) 201210483077

(51) Int. Cl. H01L 27/115

(52) U.S. Cl. CPC H01L 27/11568

(57) ABSTRACT

Provided is a non-volatile memory including a substrate having at least one protruding part, a charge trapping layer and a gate layer. The charge trapping layer covers a portion of the surface of the substrate beside the protruding part and covers at least a portion of the sidewall of the protruding part. The gate layer is disposed on the charge trapping layer. In such disposition of the invention, adjacent bits can be isolated by the protruding part of the substrate, so as to avoid mutual interference between the bits and thereby improve the performance and reliability of the device.

### BACKGROUND OF THE INVENTION

1. Field of Invention

The present invention relates to a semiconductor device and a method of forming the same, and more generally to a non-volatile memory and a method of forming the same.

2. Description of Related Art

Among various types of memory products, a non-volatile memory allows multi-time data programming, reading and erasing operations, and the data stored therein can be retained even after the power to the memory is terminated. With these advantages, the non-volatile memory has become one of the most widely adopted memories for personal computers and electronic equipment.

In a conventional two-bit/cell non-volatile memory, two bits are stored in the silicon nitride layer respectively approximate to the source region and the drain region. However, when such non-volatile memory is operated, the two bits in the same memory cell are mutually affected, and the performance and relibility of the device are accordingly reduced.

### SUMMARY OF THE INVENTION

The present invention provides a non-volatile memory and a method of forming the same, in which adjacent bits can be isolated by the protruding part of the substrate, so that the conventional mutual interference between the bits is not observed.

The present invention provides a non-volatile memory, which includes a substrate having at least one protruding part, a charge trapping layer and a gate layer. The charge trapping layer covers a portion of the surface of the substrate beside the protruding part and covers at least a portion of the sidewall of the protruding part. The gate layer is disposed on the charge trapping layer.

According to an embodiment of the present invention, the charge trapping layer further covers a top of the protruding part.

According to an embodiment of the present invention, the charge trapping layer exposes a top of the protruding part.

According to an embodiment of the present invention, the non-volatile memory further includes a cap layer covering the exposed top of the protruding part.

According to an embodiment of the present invention, the cap layer includes silicon oxide.

According to an embodiment of the present invention, the charge trapping layer includes an oxide-nitride-oxide composite layer.

According to an embodiment of the present invention, the substrate includes silicon.

According to an embodiment of the present invention, the non-volatile memory further includes two doped regions disposed in the substrate beside the charge trapping layer.

According to an embodiment of the present invention, the protruding part has an inclined sidewall.

According to an embodiment of the present invention, the gate layer surrounds the protruding part.

The present invention further provides a method of forming a non-volatile memory, which includes: providing a substrate having at least one protruding part; forming a charge trapping material layer on the substrate; forming a gate material layer on the charge trapping material layer; and patterning the charge trapping material layer and the gate material layer, so as to form a charge trapping layer that covers a portion of a surface of the substrate beside the protruding part and covers at least a portion of a sidewall of the protruding part, and form a gate layer on the charge trapping layer.

According to an embodiment of the present invention, the charge trapping layer covers a top of the protruding part.

According to an embodiment of the present invention, after the step of forming the charge trapping material layer and before the step of foaming the gate material layer, the method further includes partially removing the charge trapping material layer until a top of the protruding part is exposed.

According to an embodiment of the present invention, the step of partially removing the charge trapping material layer includes: forming a mask layer that covers a portion of the charge trapping material layer while exposes another portion of the charge trapping material layer; and removing the exposed portion of the charge trapping material layer.

According to an embodiment of the present invention, the mask layer includes photoresist or amorphous carbon.

According to an embodiment of the present invention, the method further includes forming a cap layer covering the exposed top of the protruding part.

According to an embodiment of the present invention, the charge trapping layer includes an oxide-nitride-oxide composite layer.

According to an embodiment of the present invention, the substrate includes silicon.

According to an embodiment of the present invention, the method further includes foaming two doped regions in the substrate beside the charge trapping layer.

According to an embodiment of the present invention, the protruding part has an inclined sidewall.

In view of the above, in the non-volatile memory of the invention, the protruding part of the substrate is interposed between adjacent bits stored in the charge trapping layer, so that the isolation between the bits are improved, and the conventional mutual interference between the bits is not observed. Besides, with the disposition of the protruding part, the contact area between the charge trapping layer and the gate layer can be greatly increased, and thus, the control capability of the gate layer can be significantly improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1C are schematic cross-sectional views of a method of forming a non-volatile memory according to an embodiment of the present invention.

FIG. 2A to FIG. 2C are schematic cross-sectional views of a method of forming a non-volatile memory according to another embodiment of the present invention.

FIG. 3 is a schematic cross-sectional view of a non-volatile memory according to yet another embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

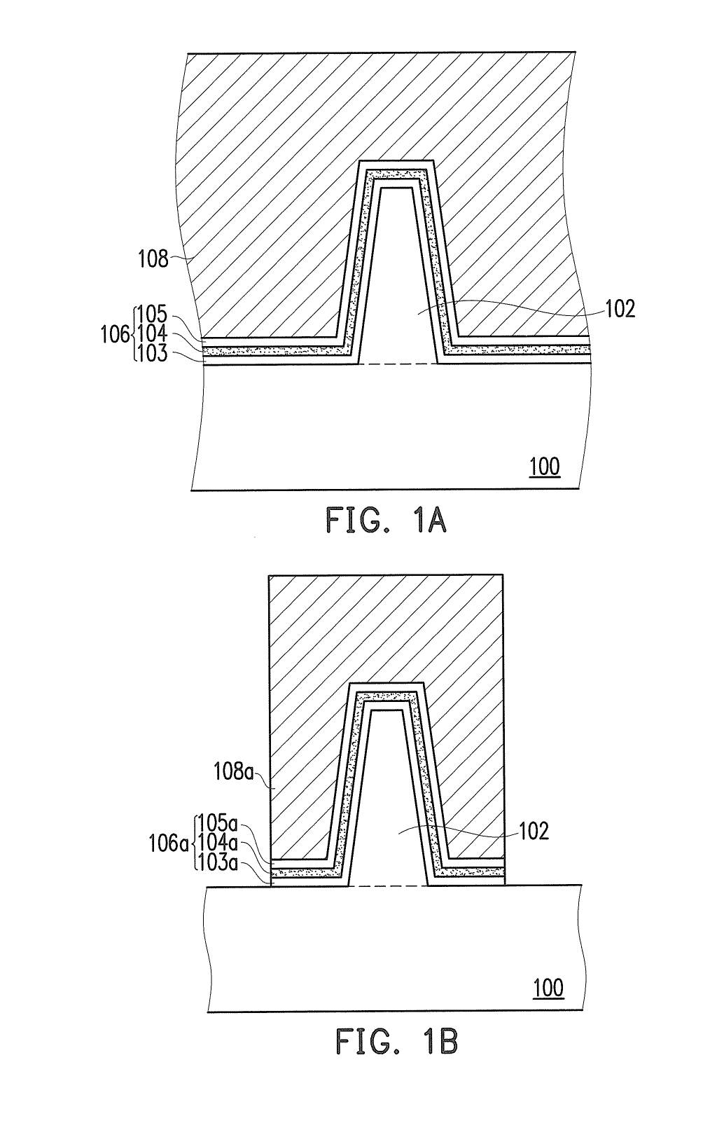

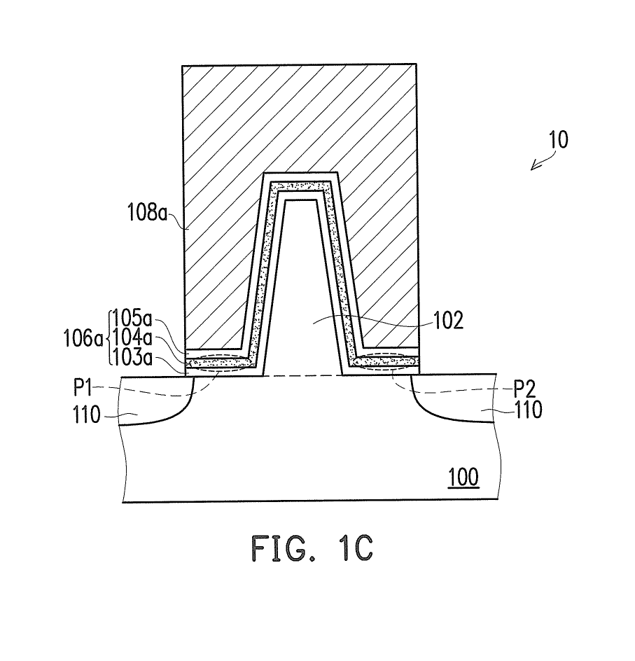

FIG. 1A to FIG. 1C are schematic cross-sectional views of a method of forming a non-volatile memory according to an embodiment of the present invention.

Referring to FIG. 1A, a substrate 100 is provided. The substrate 100 includes a semiconductor material, such as silicon. In an embodiment, the substrate 100 has at least one protruding part 102 shaped in an island or fin form. In an embodiment, the protruding part 102 has an incline sidewall, but the present invention is not limited thereto. In another embodiment, the protruding part 102 has a substantially vertical sidewall. Besides, the protruding part 102 has a substantially planar top surface. The method of forming the substrate 100 with such protruding part 102 includes performing at least one photolithography and etching process.

Thereafter, a charge trapping material layer 106 is formed conformally on the substrate 100. Specifically, the charge trapping material layer 106 covers the surface of the substrate 100 and the sidewall and top of the protruding part 102. In an embodiment, the charge trapping material layer 106 can be an oxide-nitride-oxide (ONO) composite layer including a lower oxide material layer 103, a nitride material layer 104 and an upper oxide material layer 105. The method of forming the charge trapping material layer 106 includes performing at least one suitable deposition process, such as a chemical vapour deposition (CVD) process or an atomic layer deposition (ALD) process.

Afterwards, a gate material layer 108 is formed on the charge trapping material layer 106. In an embodiment, when the substrate 100 is provided with multiple protruding parts, the gate material layer 108 fills up the space between the protruding parts. The gate material layer 108 includes doped polysilicon or polycide, and the forming method thereof includes performing a suitable deposition process, such as a CVD process or an ALD process.

Referring to FIG. 1B, the gate material layer 108 and the charge trapping material layer 106 are patterned, so as to form a gate layer 108a and a charge trapping layer 106a including a lower oxide layer 103a, a nitride layer 104a and an upper oxide layer 105a. Specifically, the charge trapping layer 106a covers a portion of the surface of the substrate 100 beside the protruding part 102 and covers the entire sidewall and top of the protruding part 102. The gate layer 108a is formed on the charge trapping layer 106a. In an embodiment, the gate layer 108a surrounds the protruding part 102. The patterning step includes performing a photolithography and etching process.

Referring to FIG. 1C, two doped regions 110 are formed in the substrate 100 beside the charge trapping layer 106a. In an embodiment, the doped regions 110 are extended to below a portion of the charge trapping layer 106a. The method of forming the doped regions 110 includes performing an ion implantation step. The non-volatile memory 10 of the present invention is thus completed.

The non-volatile memory structure of the invention is illustrated with reference to FIG. 1C in the following. The non-volatile memory 10 of the invention includes a substrate 100 having at least one protruding part 102, a charge trapping layer 106a, a gate layer 108a and doped regions 110. The charge trapping layer 106a covers a portion of the surface of the substrate 100 beside the protruding part 102 and covers at least a portion of the sidewall of the protruding part 102. In this embodiment, the charge trapping layer 106a covers the entire sidewall and top of the protruding part 102. The doped regions 110 are disposed in the substrate 100 beside the charge trapping layer 106a.

In the non-volatile memory of FIG. 1C, two bits are stored in the positions P1 and P2 of the nitride layer 104a of the charge trapping layer 106a respectively approximate to the doped regions 110 as source/drain regions. Since the protruding part 102 of the substrate 100 is interposed between the two bits, the isolation between the bits are improved, so the bits can be operated well without mutual interference.

The said embodiment in which the entire surface of the protruding part of the substrate is covered by the charge trapping layer is provided for illustration purposes, and is not construed as limiting the present invention. In another embodiment, the charge trapping layer can be discontinuous and the top or upper portion of the protruding part of the substrate can be exposed.

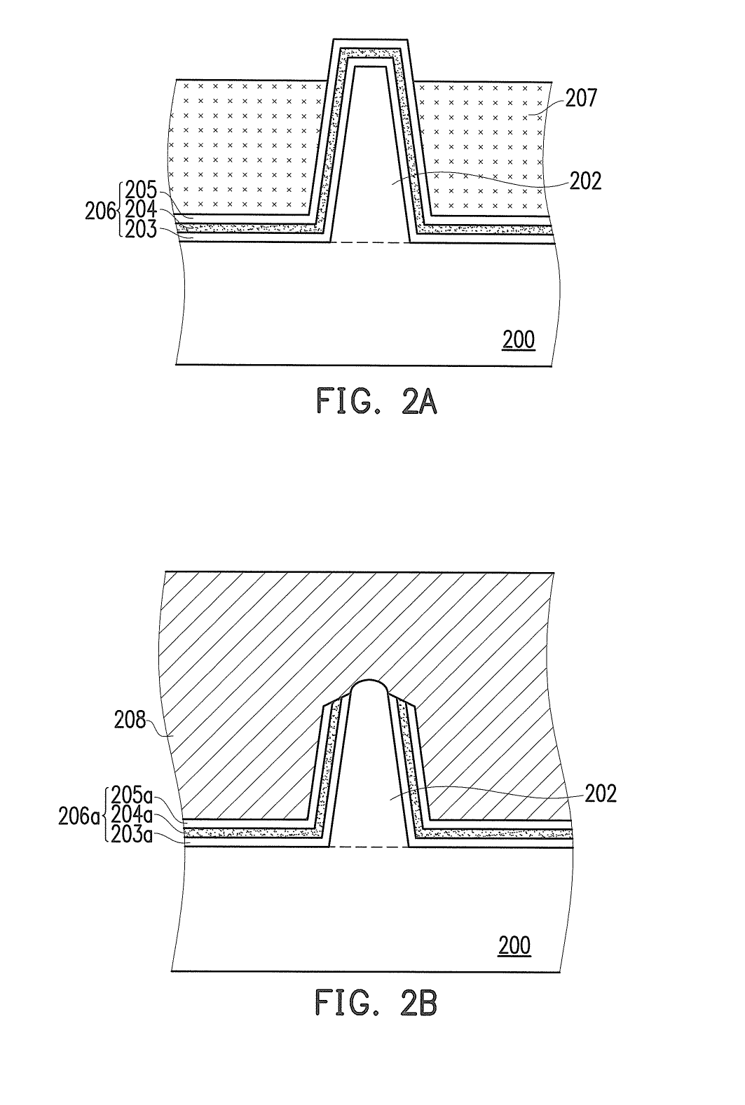

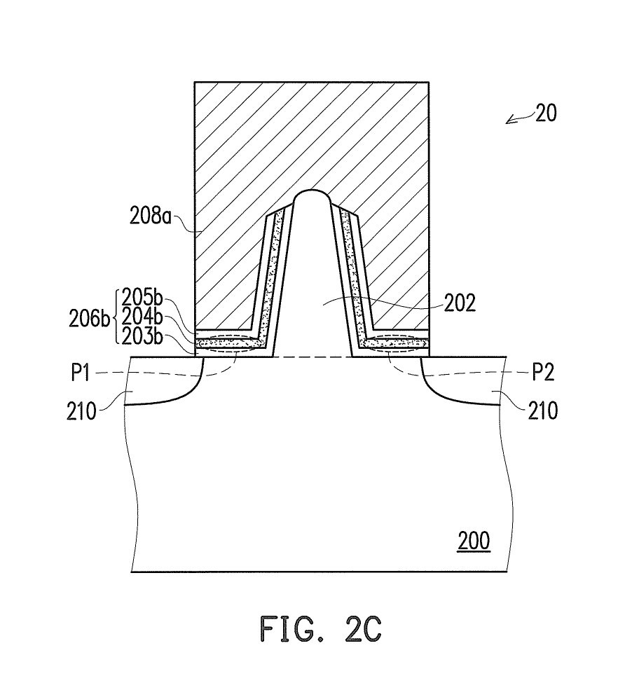

FIG. 2A to FIG. 2C are schematic cross-sectional views of a method of forming a non-volatile memory according to another embodiment of the present invention.

Referring to FIG. 2A, a substrate 200 is provided. The substrate 200 includes a semiconductor material, such as silicon. In an embodiment, the substrate 200 has at least one protruding part 202 shaped in an island or fin form. In an embodiment, the protruding part 202 has an incline sidewall and a substantially planar top surface. The method of foil ling the substrate 200 with such protruding part 202 includes performing at least one photolithography and etching process.

Thereafter, a charge trapping material layer 206 is formed conformally on the substrate 200. Specifically, the charge trapping material layer 206 covers the surface of the substrate 100 and the sidewall and top of the protruding part 202. In an embodiment, the charge trapping material layer 206 can be an oxide-nitride-oxide (ONO) composite layer including a lower oxide material layer 203, a nitride material layer 204 and an upper oxide material layer 205. The method of forming the charge trapping material layer 206 includes performing at least one suitable deposition process, such as a CVD process or an ALD process.

Afterwards, a mask layer 207 is formed to cover the lower portion of the protruding part 202. In an embodiment, when the substrate 200 is provided with multiple protruding parts, the mask layer 207 fills the lower portion of the space between the protruding parts. The mask layer 207 includes photoresist or amorphous carbon. In an embodiment, the mask layer 207 includes Advanced Pattering Film™ (APF) available from Applied Material, Inc. of Santa Clara, Calif. The method of forming the mask layer 207 includes the following steps. A mask material layer (not shown) is formed on the substrate 200 covering the protruding part 202 with a spin coating or a suitable deposition process. Thereafter, a portion of the mask material layer is removed through an etching back or a chemical mechanical polishing (CMP) process, until the top surface of the remaining mask material layer (i.e., mask layer 207) is lower than the top surface of the protruding part 202. Specifically, the mask layer 207 covers a portion of the charge trapping material layer 206 while exposes another portion of the charge trapping material layer 206 around the top of the protruding part 202.

Referring to FIG. 2B, the portion of the charge trapping material layer 206 exposed by the mask layer 207 is removed, and thus, the top of the protruding part 202 is exposed and the remaining charge trapping material layer 206a is provided to include a lower oxide material layer 203a, a nitride material layer 204a and an upper oxide material layer 205a. Specifically, upon the removing step, the charge trapping material layer 206 is broken from the uppermost point thereof and divided into two stripes disposed symmetrically with respect to the central protruding part 202. The charge trapping material layer 206 can be partially removed with an etching back or a CMP process. In an embodiment, only the top or the top surface of the protruding part 202 is exposed, but the invention is not limited thereto. In another embodiment, the top surface and the upper sidewall of the protruding part 202 can be exposed. Besides, the top of the protruding part 202 may be rounded upon the partial removal of the charge trapping material layer 206, as shown in FIG. 2B. The mask layer 207 is then removed through an etching process.

Afterwards, a gate material layer 208 is formed on the substrate 200 covering the charge trapping material layer 206a and the exposed top of the protruding part 202. In an embodiment, when the substrate 200 is provided with multiple protruding parts, the gate material layer 208 fills up the space between the protruding parts. The gate material layer 208 includes doped polysilicon or polycide, and the forming method thereof includes performing a suitable deposition process, such as a CVD process or an ALD process.

Referring to FIG. 2C, the gate material layer 208 and the charge trapping material layer 206a are patterned, so as to form a gate layer 208a and a charge trapping layer 206b including a lower oxide layer 203b, a nitride layer 204b and an upper oxide layer 205b. Specifically, the charge trapping layer 206b covers a portion of the surface of the substrate 200 beside the protruding part 202 and covers the sidewall but exposes the top of the protruding part 202. The gate layer 208a is foamed on the charge trapping layer 206b. In an embodiment, the gate layer 208a surrounds the protruding part 202. The patterning step includes performing a photolithography and etching process.

Thereafter, two doped regions 210 are formed in the substrate 200 beside the charge trapping layer 206b. In an embodiment, the doped regions 210 are extended to below a portion of the charge trapping layer 206b. The method of forming the doped regions 210 includes performing an ion implantation step. The non-volatile memory 20 of the present invention is thus completed.

The non-volatile memory structure of the invention is illustrated with reference to FIG. 2C in the following. The non-volatile memory 20 of the invention includes a substrate 200 having at least one protruding part 202, a charge trapping layer 206b, a gate layer 208a and doped regions 210. The charge trapping layer 206b covers a portion of the surface of the substrate 200 beside the protruding part 202 and covers at least a portion of the sidewall of the protruding part 202. In this embodiment, the charge trapping layer 206b covers the sidewall but exposes the top of the protruding part 202. The doped regions 210 are disposed in the substrate 100 beside the charge trapping layer 206b.

In the non-volatile memory of FIG. 2C, two bits are stored in the positions P1 and P2 of the nitride layer 204b of the charge trapping layer 206b respectively approximate to the doped regions 210 as source/drain regions. Since the protruding part 202 of the substrate 200 is interposed between the two bits and the top thereof is further exposed, the isolation between the bits can be further improved, so the bits can be operated well without mutual interference.

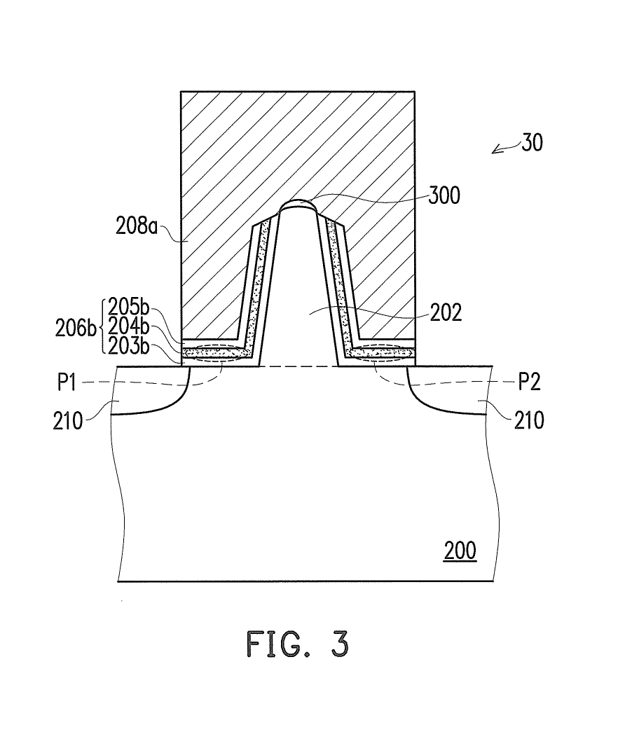

In another embodiment, after the step of breaking the charge trapping material layer 206 (FIG. 2B) and before the step of forming the gate material layer 208 (FIG. 2C), a cap layer 300 can be optionally formed to cover the exposed top of the protruding part 202, as shown in the non-volatile memory 30 of FIG. 3. The cap layer 300 includes silicon oxide, and the forming method thereof includes performing a thermal oxidation process. In an embodiment, the exposed surface portion of the silicon nitride 204b of the charge trapping layer 206b can be oxidized to silicon oxynitride during the step of forming the cap layer 300. The insulating cap layer 300 provides an additional isolation effect between the adjacent bits.

The said embodiments with two bits illustrated are provided for illustration purposes, and are not contruded as limiting the present invention. In other words, the present invention can be applied to a multi-cell memory with three bits or more, as long as an insulating protruding part is provided between the adjacnet bits.

In summary, in the non-volatile memory of the invention, the protruding part of the substrate is interposed between adjacent bits stored in the charge trapping layer, so that the isolation between the bits can be successfully achieved. Besides, the contact area between the charge trapping layer and the gate layer can be greatly increased due to the disposition of the protruding part, and thus, the control capability of the gate layer can be significantly improved. In an embodiment, the protruding part has an inclined sidewall beneficial to further increase the contact area between the charge trapping layer and the gate layer. In such disposition of the invention, the conventional mutual interference between the bits is not observed, so the performance and relibility of the device are accordingly increased.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A non-volatile memory, comprising:
a substrate having at least one protruding part;
a charge trapping layer, covering a portion of a surface of the substrate beside the protruding part and covering at least a portion of a sidewall of the protruding part; and
a gate layer, disposed on the charge trapping layer.

2. The non-volatile memory of claim 1, wherein the charge trapping layer further covers a top of the protruding part.

3. The non-volatile memory of claim 1, wherein the charge trapping layer exposes a top of the protruding part.

4. The non-volatile memory of claim 3, further comprising a cap layer covering the exposed top of the protruding part.

5. The non-volatile memory of claim 4, wherein the cap layer comprises silicon oxide.

6. The non-volatile memory of claim 1, wherein the charge trapping layer comprises an oxide-nitride-oxide composite layer.

7. The non-volatile memory of claim 1, wherein the substrate comprises silicon.

8. The non-volatile memory of claim 1, further comprising two doped regions disposed in the substrate beside the charge trapping layer.

9. The non-volatile memory of claim 1, wherein the protruding part has an inclined sidewall.

10. The non-volatile memory of claim 1, wherein the gate layer surrounds the protruding part.

11. A method of forming a non-volatile memory, comprising:
providing a substrate having at least one protruding part;
forming a charge trapping material layer on the substrate;
forming a gate material layer on the charge trapping material layer; and
patterning the charge trapping material layer and the gate material layer, so as to form a charge trapping layer that covers a portion of a surface of the substrate beside the protruding part and covers at least a portion of a sidewall of the protruding part, and form a gate layer on the charge trapping layer.

12. The method of claim 11, wherein the charge trapping layer covers a top of the protruding part.

13. The method of claim 11, further comprising, after the step of forming the charge trapping material layer and before the step of forming the gate material layer, partially removing the charge trapping material layer until a top of the protruding part is exposed.

14. The method of claim 13, wherein the step of partially removing the charge trapping material layer comprises:
forming a mask layer that covers a portion of the charge trapping material layer while exposes another portion of the charge trapping material layer; and
removing the exposed portion of the charge trapping material layer.

15. The method of claim 14, wherein the mask layer comprises photoresist or amorphous carbon.

16. The method of claim 13, further comprising forming a cap layer covering the exposed top of the protruding part.

17. The method of claim 11, wherein the charge trapping layer comprises an oxide-nitride-oxide composite layer.

18. The method of claim 11, wherein the substrate comprises silicon.

19. The method of claim 11, further comprising forming two doped regions in the substrate beside the charge trapping layer.

20. The method of claim 11, wherein the protruding part has an inclined sidewall.
